(19) United States
(12) Patent Application Publication
(10) Pub. No.: US 2026/0333964 A1
(43) Pub. Date: Oct. 22, 2026

(54) MICRO LIGHT EMITTING DIODE CHIP AND METHOD FOR FORMING THE SAME

(71) Applicant: HUE INC., Shanghai (CN)

(72) Inventors: Chengzhen BAI, Shanghai (CN); Feng FENG, Shanghai (CN); Jian GUO, Shanghai (CN)

(73) Assignee: HUE INC., Shanghai (CN)

(21) Appl. No.: 19/533,293

(22) Filed: Feb. 9, 2026

(30) Foreign Application Priority Data
Feb. 10, 2025 (CN) 202510148297.4

(51) Int. Cl. H10H 29/14; H10H 29/80

(52) U.S. Cl. CPC H10H 29/142; H10H 29/842

(57) ABSTRACT

A micro light emitting diode chip and a method for forming the same, the micro light emitting diode chip includes a first light emitting part including several first pixel structures, each of which emits light with a first wavelength; and a second light emitting part including several second pixel structures, each of which emits light with a second wavelength different from the first wavelength; the first light emitting part and the second light emitting part are connected by bonding, and the first pixel structures and the second pixel structures corresponding thereto are provided relative to each other along a stacking direction of components. With light emitting pixel structures emitting light with different wavelengths being integrated into a same chip, stacking of pixel structures of different colors can be completed at a same chip end, which can effectively reduce a volume of chips of different colors which are used in combination.

### CROSS-REFERENCE TO RELATED APPLICATIONS

This application claims the benefit of priority to Chinese Patent Application No. 2025101482974, filed on Feb. 10, 2025 with China National Intellectual Property Administration, and entitled “MICRO LIGHT EMITTING DIODE CHIP AND METHOD FOR FORMING THE SAME”, the entire disclosure of which is incorporated herein by reference.

### Field

The present disclosure relates to the field of microdisplay technology, and more particularly, to a micro light emitting diode chip and a method for forming the same.

### BACKGROUND

Inorganic micro pixel light emitting diodes are also known as micro light emitting diodes (Micro LED or μ-LED). Micro light emitting diode technology is a high pixel density LED flat panel display technology that uses a micron-scale LED as a pixel element, assembled on a CMOS backplane in micron-scale periodic arrays. A display principle of the micro light emitting diode technology involves designing a structure of the LED to be thin film, miniaturized, and arrayed, with a size ranging from a few microns to several tens of microns, and then massively transferring the micro light emitting diode chips onto a TFT or CMOS backplane. Micro light emitting diode displays feature excellent properties, such as, high light emitting efficiency, high brightness, fast response time, and good reliability, and are thus regarded by the industry as a next-generation display technology and an ultimate form of display.

However, existing micro light emitting diode chips still have many problems.

### SUMMARY

The present disclosure provides a micro light emitting diode chip and a method for forming the same, to reduce a volume of chips of different colors which are used in combination.

Embodiments of the present disclosure provide a micro light emitting diode chip. The micro light emitting diode chip includes a first light emitting part including several discrete first pixel structures, each of the first pixel structures emits light with a first wavelength; and a second light emitting part including several second pixel structures corresponding to the first pixel structures, each of the second pixel structures emits light with a second wavelength, and the first wavelength is different from the second wavelength; the first light emitting part and the second light emitting part are connected by bonding, and the first pixel structures and the second pixel structures corresponding thereto are provided relative to each other along a stacking direction of components.

In some embodiments, the first light emitting part further includes a first dielectric layer disposed on and covering the first pixel structures; the second light emitting part further includes a second dielectric layer disposed on and covering the second pixel structures; the first dielectric layer and the second dielectric layer are connected by bonding, to connect the first light emitting part and the second light emitting part by bonding.

In some embodiments, along the stacking direction of components, the first pixel structures have a first projection region, the second pixel structures corresponding to the first pixel structures have a second projection region, and the first projection region and the second projection region are completely or at least partially overlapping.

In some embodiments, the first pixel structures include a first epitaxial layer, a second epitaxial layer, and a first multiple quantum well layer disposed between the first epitaxial layer and the second epitaxial layer; the first epitaxial layer contains a first doped ion, the second epitaxial layer contains a second doped ion, and electrical types of the first doped ion and the second doped ion are different.

In some embodiments, the first light emitting part further includes a metal layer; the metal layer includes several first metal strips arranged in parallel in a first direction and extending in a second direction, the first direction is perpendicular to the second direction; a first bus extending in the first direction, and the several first metal strips are electrically connected to the first bus, respectively; several second metal strips arranged in parallel in the first direction and extending in the second direction, the several first metal strips and the several second metal strips are arranged at intervals; and a second bus extending in the first direction, and the several second metal strips are electrically connected to the second bus, respectively.

In some embodiments, the metal layer is made of a non-transparent metal material; and the non-transparent metal material includes chromium, titanium, platinum, gold, tin, aluminum, nickel, copper, or silver.

In some embodiments, the first pixel structures are electrically connected with the several first metal strips, respectively, and the first pixel structures are arranged in an array along the first direction and the second direction.

In some embodiments, the first epitaxial layer of the first pixel structures is electrically connected with the several first metal strips, respectively.

In some embodiments, the first light emitting part further includes a first ohmic contact layer disposed on the first metal strips, on the second metal strips, on the first bus and on the second bus; and the first pixel structures are electrically connected with the first ohmic contact layer, respectively.

In some embodiments, the first epitaxial layer of the first pixel structures is electrically connected with several of the first ohmic contact layers, respectively.

In some embodiments, the first ohmic contact layer is made of a material including a transparent metal material; and the transparent metal material includes indium tin oxide.

In some embodiments, the first light emitting part further includes several second ohmic contact layers arranged in parallel in the second direction and extending in the first direction, and each of the second ohmic contact layers is electrically connected with the first pixel structures arranged in the first direction, respectively.

In some embodiments, the first dielectric layer includes a first dielectric sublayer disposed on and covering the first pixel structures, and the second ohmic contact layers are disposed on the first dielectric sublayer.

In some embodiments, the first dielectric layer further includes a second dielectric sublayer disposed on the first dielectric sublayer and covering the second ohmic contact layers.

In some embodiments, the second ohmic contact layers are made of a material including a transparent metal material; and the transparent metal material includes indium tin oxide.

In some embodiments, the second dielectric sublayer is connected with the second dielectric layer by bonding.

In some embodiments, the first light emitting part further includes several first conductive plugs electrically connected with the several second ohmic contact layers, respectively; several second conductive plugs electrically connected with the several second metal strips, respectively; several third conductive plugs electrically connected with the first bus, respectively; and several fourth conductive plugs electrically connected with the second bus, respectively.

In some embodiments, the second pixel structures include a third epitaxial layer, a fourth epitaxial layer, and a second multiple quantum well layer disposed between the third epitaxial layer and the fourth epitaxial layer; the third epitaxial layer contains the first doped ion, and the fourth epitaxial layer contains the second doped ion.

In some embodiments, the fourth epitaxial layers of the several second pixel structures are connected to each other.

In some embodiments, the second light emitting part further includes several third ohmic contact layers, each of the third ohmic contact layers is electrically connected to a corresponding second pixel structure.

In some embodiments, each of the third ohmic contact layers is electrically connected with the third epitaxial layer of the corresponding second pixel structure.

In some embodiments, the third ohmic contact layers are made of a material including a transparent metal material; the transparent metal material includes indium tin oxide.

In some embodiments, the second dielectric layer further covers the several third ohmic contact layers.

In some embodiments, the second light emitting part further includes several fifth conductive plugs electrically connected with the fourth epitaxial layer of the second pixel structures, respectively and connected with corresponding several first conductive plugs by bonding, respectively; several sixth conductive plugs electrically connected with a corresponding third ohmic contact layer, respectively and connected with corresponding several second conductive plugs by bonding, respectively; several seventh conductive plugs electrically connected with corresponding several third conductive plugs, respectively; and several eighth conductive plugs electrically connected with corresponding several fourth conductive plugs, respectively.

In some embodiments, the micro light emitting diode chip further includes a first electrode plate electrically connected with the several fifth conductive plugs; a second electrode plate electrically connected with the several seventh conductive plugs; and a third electrode plate electrically connected with the several eighth conductive plugs.

The embodiments of the present disclosure further provide a method for forming a micro light emitting diode chip. The method includes forming a first light emitting part, and forming the first light emitting part includes forming several discrete first pixel structures, each of the first pixel structures emits light with a first wavelength; forming a second light emitting part, forming the second light emitting part includes forming several second pixel structures corresponding to the first pixel structures, each of the second pixel structures emits light with a second wavelength, and the first wavelength is different from the second wavelength; and bonding the first light emitting part and the second light emitting part, and the first pixel structures and the second pixel structures corresponding thereto are provided relative to each other along a stacking direction of components.

In some embodiments, forming the first light emitting part further includes forming a first dielectric layer on the first pixel structures, and the first dielectric layer covers the first pixel structures; forming the second light emitting part further includes forming a second dielectric layer on the second pixel structures, and the second dielectric layer covers the second pixel structures; and bonding the first dielectric layer and the second dielectric layer, to connect the first light emitting part and the second light emitting part by bonding.

In some embodiments, along the stacking direction of components, the first pixel structures have a first projection region, the second pixel structures corresponding to the first pixel structures have a second projection region, and the first projection region and the second projection region are completely or at least partially overlapping.

In some embodiments, forming the first pixel structures includes forming a first epitaxial layer, a second epitaxial layer, and a first multiple quantum well layer disposed between the first epitaxial layer and the second epitaxial layer; the first epitaxial layer contains a first doped ion, the second epitaxial layer contains a second doped ion, and electrical types of the first doped ion and the second doped ion are different.

In some embodiments, forming the first light emitting part further includes forming a metal layer; forming the metal layer includes forming several first metal strips arranged in parallel in a first direction and extending in a second direction, the first direction is perpendicular to the second direction; forming a first bus extending in the first direction, and the several first metal strips are electrically connected with the first bus, respectively; forming several second metal strips arranged in parallel in the first direction and extending in the second direction, and the several first metal strips and the several second metal strips are arranged at intervals; and forming a second bus extending in the first direction, and the several second metal strips are electrically connected with the second bus, respectively.

In some embodiments, the metal layer is made of a non-transparent metal material.

In some embodiments, the first pixel structures are electrically connected with the several first metal strips, respectively, and the first pixel structures are arranged in an array along the first direction and the second direction.

In some embodiments, the first epitaxial layer of the first pixel structures is electrically connected with the several first metal strips, respectively.

In some embodiments, forming the first light emitting part further includes forming a first ohmic contact layer on the first metal strips, on the second metal strips, on the first bus and on the second bus; the first pixel structures are electrically connected with the first ohmic contact layer, respectively.

In some embodiments, a method for forming the metal layer and the first ohmic contact layer includes forming a metal material layer; forming a first ohmic contact material layer on the metal material layer; and etching the metal material layer and the first ohmic contact material layer, to form the metal layer and the first ohmic contact layer.

In some embodiments, the first epitaxial layer of the first pixel structures is electrically connected with several of the first ohmic contact layers, respectively.

In some embodiments, forming the first light emitting part further includes forming several second ohmic contact layers arranged in parallel in the second direction and extending in the first direction, and each of the second ohmic contact layers is electrically connected with the first pixel structures arranged in the first direction.

In some embodiments, forming the first dielectric layer includes forming a first dielectric sublayer disposed on and covering the first pixel structures, and the second ohmic contact layers are disposed on the first dielectric sublayer.

In some embodiments, forming the first dielectric layer further includes forming a second dielectric sublayer disposed on the first dielectric sublayer and covering the second ohmic contact layers.

In some embodiments, upon bonding the first light emitting part and the second light emitting part, the second dielectric sublayer is connected with the second dielectric layer.

In some embodiments, forming the first light emitting part further includes forming several first conductive plugs electrically connected with the several second ohmic contact layers, respectively; forming several second conductive plugs electrically connected with the several second metal strips, respectively; forming several third conductive plugs electrically connected with the first bus, respectively; and forming several fourth conductive plugs electrically connected with the second bus, respectively.

In some embodiments, forming the second pixel structures includes forming a third epitaxial layer, a fourth epitaxial layer, and a second multiple quantum well layer disposed between the third epitaxial layer and the fourth epitaxial layer; the third epitaxial layer contains the first doped ion, and the fourth epitaxial layer contains the second doped ion.

In some embodiments, the fourth epitaxial layers of the several second pixel structures are connected to each other.

In some embodiments, forming the second light emitting part further includes forming several third ohmic contact layers, and each of the third ohmic contact layers is electrically connected to a corresponding second pixel structure.

In some embodiments, each of the third ohmic contact layers is electrically connected with the third epitaxial layer of the corresponding second pixel structure.

In some embodiments, the second dielectric layer further covers the several third ohmic contact layers.

In some embodiments, forming the second light emitting part further includes forming several fifth conductive plugs electrically connected with the fourth epitaxial layer of the second pixel structure, respectively; forming several sixth conductive plugs electrically connected with a corresponding third ohmic contact layer, respectively; forming several seventh conductive plugs; forming several eighth conductive plugs; and upon bonding the first light emitting part and the second light emitting part, the several fifth conductive plugs are connected with corresponding several first conductive plugs by bonding, respectively; the several sixth conductive plugs are connected with corresponding several second conductive plugs by bonding, respectively; the several seventh conductive plugs are electrically connected with corresponding several third conductive plugs, respectively; and the several eighth conductive plugs are electrically connected with corresponding several fourth conductive plugs, respectively.

In some embodiments, after bonding the first light emitting part and the second light emitting part, the method further includes forming a first electrode plate electrically connected with the several fifth conductive plugs; forming a second electrode plate electrically connected with the several seventh conductive plugs; and forming a third electrode plate electrically connected with the several eighth conductive plugs.

The embodiments of the present disclosure have the following advantages.

The micro light emitting diode chip according to the embodiments of the present disclosure includes a first light emitting part including several discrete first pixel structures, each of the first pixel structures emits light with a first wavelength; and a second light emitting part including several second pixel structures corresponding to the first pixel structures, each of the second pixel structures emits light with a second wavelength, and the first wavelength is different from the second wavelength; the first light emitting part and the second light emitting part are connected by bonding. With light emitting pixel structures emitting light with different wavelengths being integrated into a same chip, stacking of pixel structures of different colors can be completed at a same chip end, which can effectively reduce a volume of chips of different colors which are used in combination.

Further, the metal layer is made of a non-transparent metal material, which can not only meet design requirements of the electrical connection between the first pixel structures, the non-transparent metal material can also play a role in light reflection, and can emit the light emitted from the first pixel structures and the second pixel structures towards a predetermined light emitting surface.

Further, the micro light emitting diode chip further includes a first electrode plate electrically connected with several fifth conductive plugs; a second electrode plate electrically connected with several seventh conductive plugs; and a third electrode plate electrically connected with several eighth conductive plugs. With the three electrode plates, and the first electrode plate is used as a common electrode of same doped epitaxial layers in the first pixel structures and the second pixel structures, different power supply combinations of the three electrode plates can realize monochrome light emission of the first pixel structures, monochromatic light emission of the second pixel structures, and mixed light emission of the first pixel structures and the second pixel structures, to meet requirements of a variety of use scenarios.

The method for forming a micro light emitting diode chip according to the embodiments of the present disclosure includes forming a first light emitting part including several discrete first pixel structures, each of the first pixel structures emits light with a first wavelength; forming a second light emitting part including several second pixel structures corresponding to the first pixel structures, each of the second pixel structures emits light with a second wavelength, and the first wavelength is different from the second wavelength; and bonding the first light emitting part and the second light emitting part. With light emitting pixel structures emitting light with different wavelengths being integrated into a same chip, stacking of pixel structures of different colors can be completed at a same chip end, which can effectively reduce a volume of chips of different colors which are used in combination.

Further, the metal layer is made of a non-transparent metal material, which can not only meet design requirements of the electrical connection between the first pixel structures, the non-transparent metal material can also play a role in light reflection, and can emit the light emitted from the first pixel structures and the second pixel structures towards a predetermined light emitting surface.

Further, after bonding the first light emitting part and the second light emitting part, the method further includes forming a first electrode plate electrically connected with several fifth conductive plugs; forming a second electrode plate electrically connected with several seventh conductive plugs; and forming a third electrode plate electrically connected with several eighth conductive plugs. With the three electrode plates, and the first electrode plate is used as a common electrode of same doped epitaxial layers in the first pixel structures and the second pixel structures, different power supply combinations of the three electrode plates can realize monochrome light emission of the first pixel structures, monochromatic light emission of the second pixel structures, and mixed light emission of the first pixel structures and the second pixel structures, to meet requirements of a variety of use scenarios.

### BRIEF DESCRIPTION OF THE DRAWINGS

FIGS. 1 - 34 are schematic views during procedures of a method for forming a micro light emitting diode chip according to an embodiment of the present disclosure.

### DETAILED DESCRIPTION

As mentioned in the BACKGROUND, existing micro light emitting diode chips still have many problems, which will be explained in detail below.

Current micro light emitting diode chips all emit monochromatic light, and will have a large overall volume when a plurality of micro light emitting diode chips emitting monochromatic light are used in combination, which is not conducive to integrating into electronic products for practical applications.

In view of this, the present disclosure provides a micro light emitting diode chip and a method for forming the same. With light emitting pixel structures emitting light of different colors being integrated into a same chip, stacking of pixel structures of different colors can be completed at a same chip end, which can effectively reduce a volume of chips of different colors which are used in combination.

In order to make the above-mentioned purposes, features and advantages of the present disclosure more understandable, specific embodiments of the present disclosure will be clearly and completely described below in conjunction with the accompanying drawings. It is understood that the described embodiments are only a part but not all of the embodiments of the present disclosure.

It should be understood that, in the description of the present disclosure, orientation or position relationship indicated by terms "up", "down", "top surface", "bottom surface", and the like, is based on the orientation or position relationship shown in the accompanying drawings, and is only for the convenience of describing the present disclosure and simplifying the description, rather than indicating or implying that the referred position or element must have a specific orientation, be composed and operate in a specific orientation, and therefore cannot be understood as a limitation of the present disclosure. In addition, terms "first" and "second" are used only to distinguish an entity or operation from another one entity or operation without requiring or implying any actual relationship, order, or relative importance between these entities or operations.

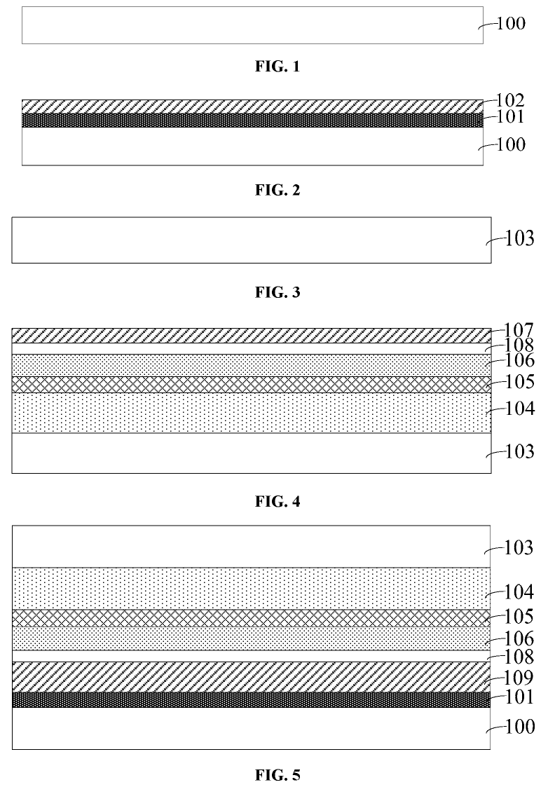

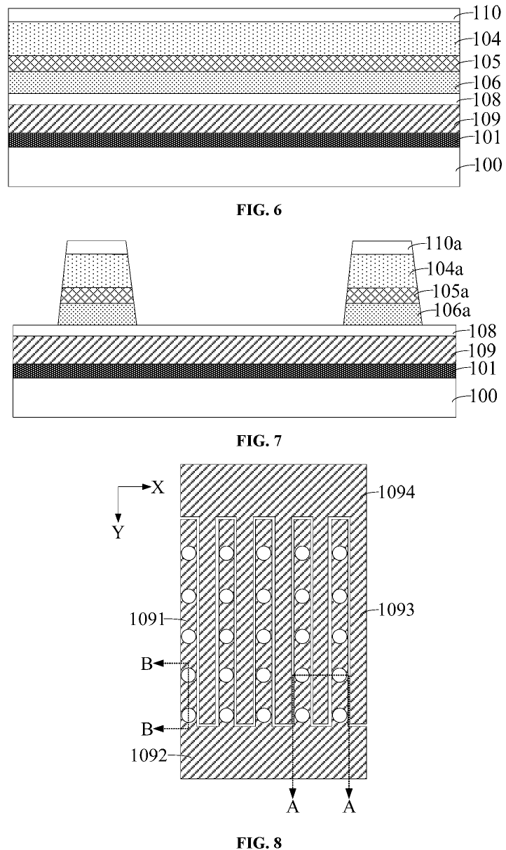

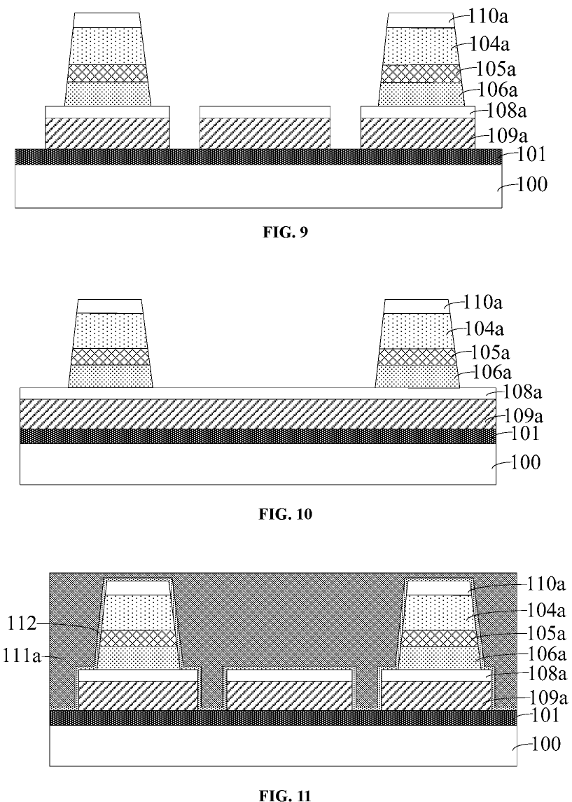

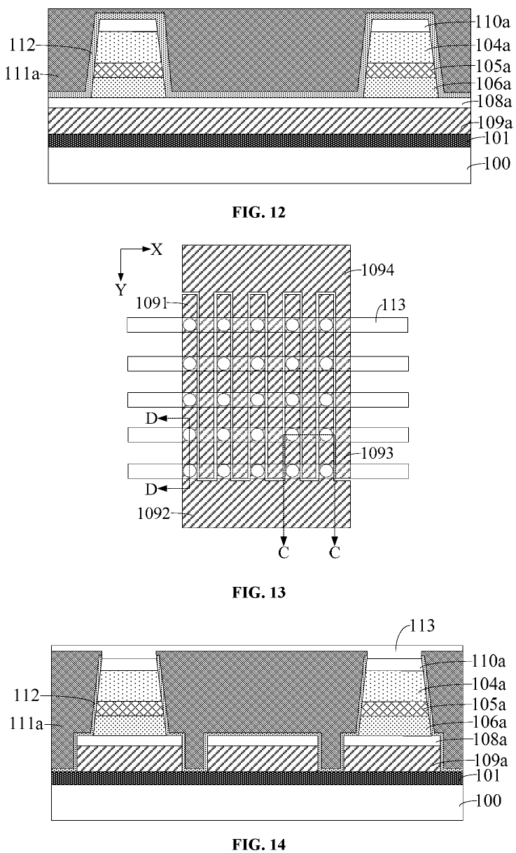

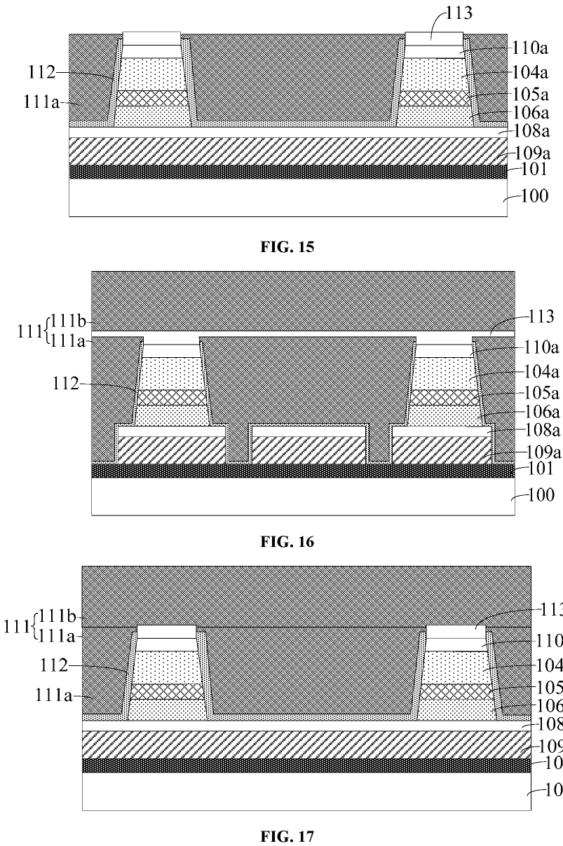

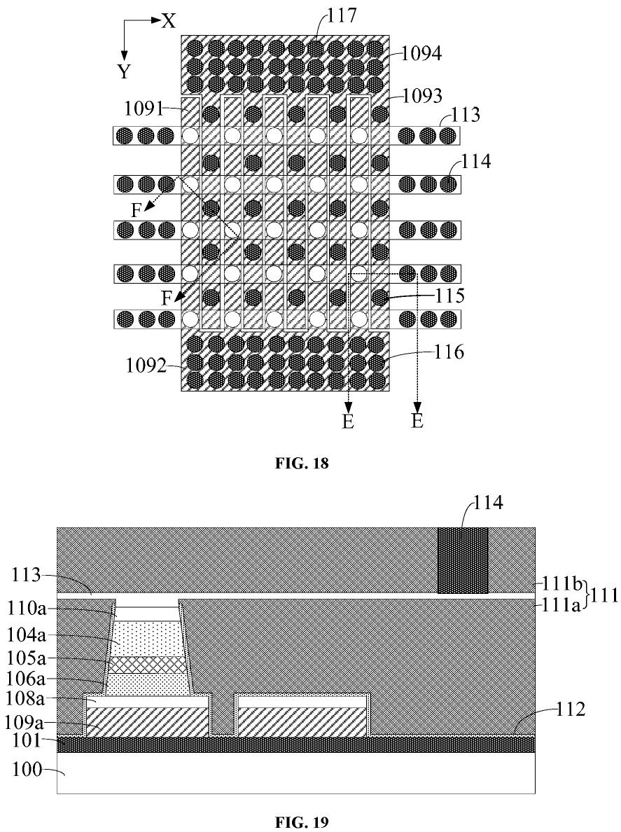

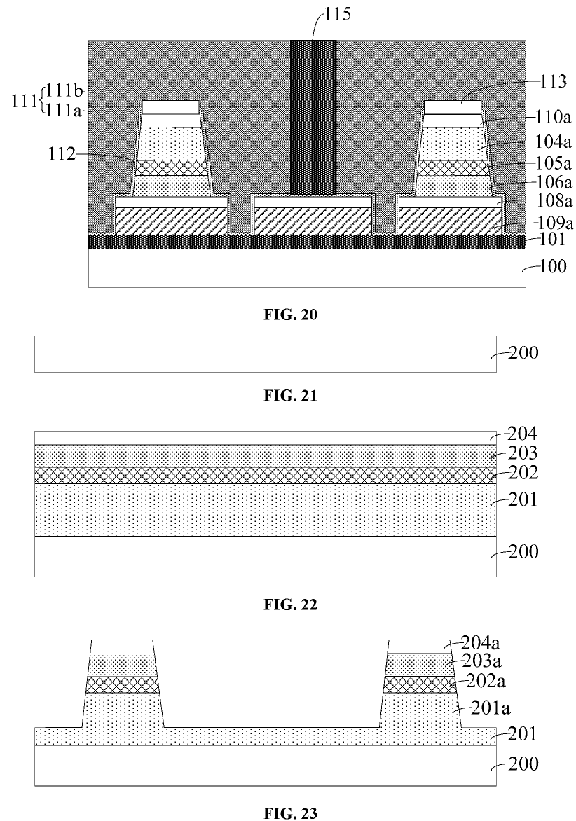

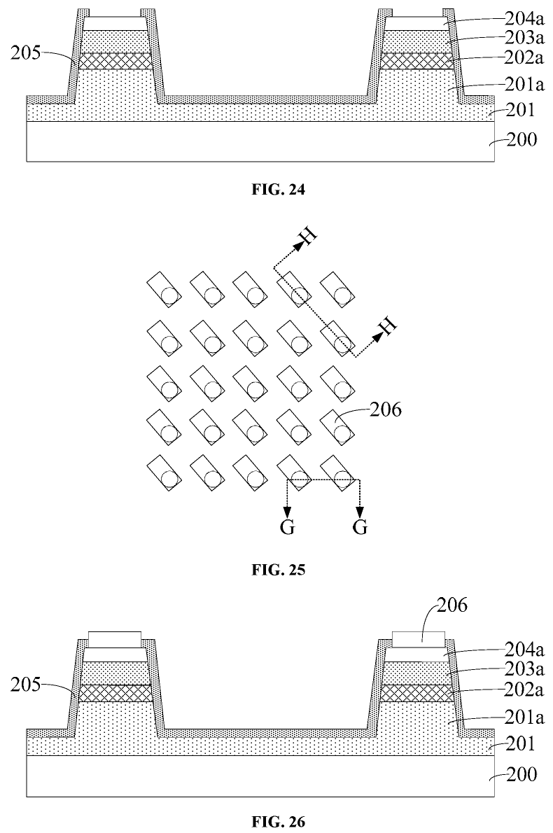

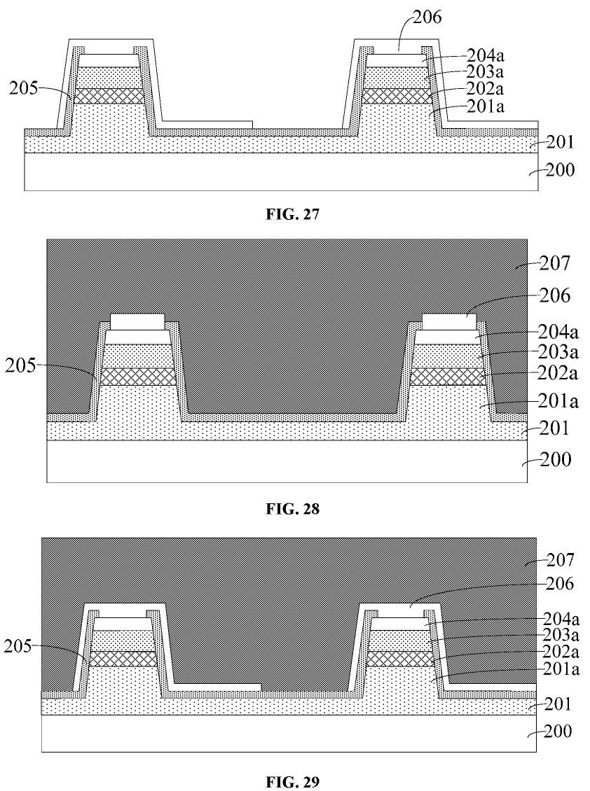

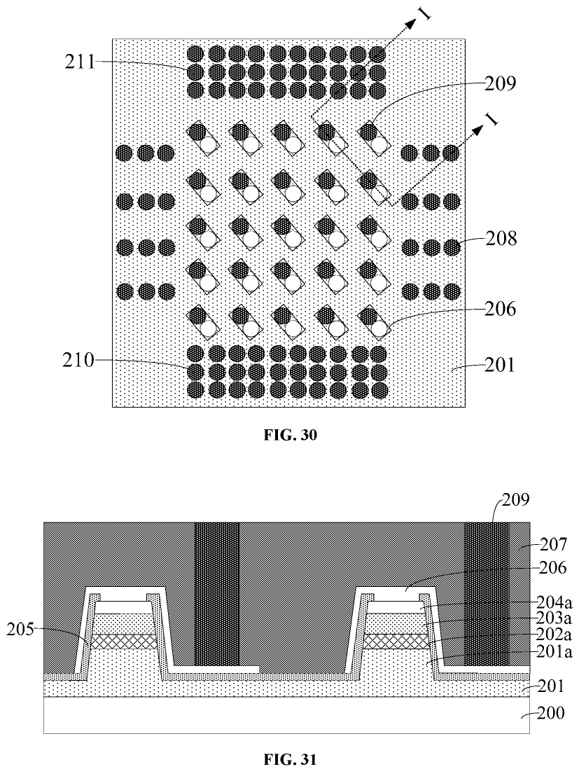

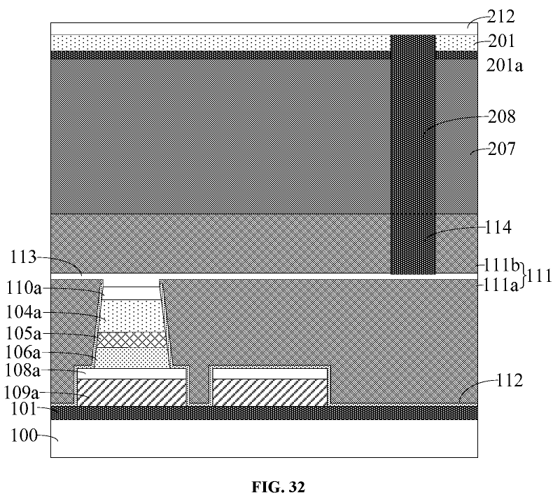

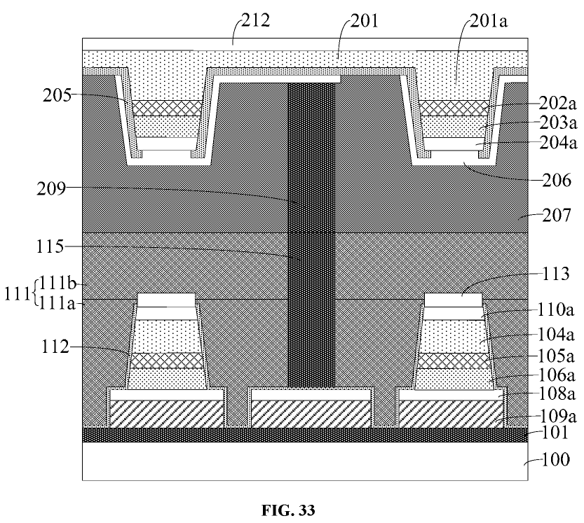

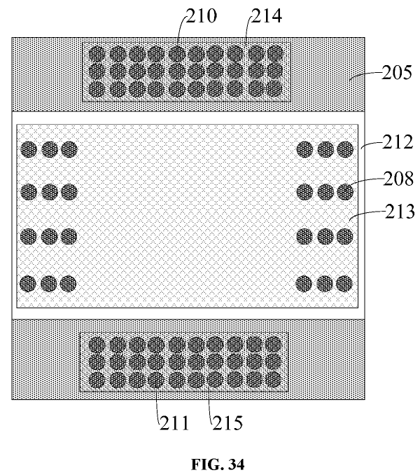

FIGS. 1 -34 are schematic views during procedures of a method for forming a micro light emitting diode chip according to an embodiment of the present disclosure.

The method for forming a micro light emitting diode chip includes forming a first light emitting part. Forming the first light emitting part includes forming several discrete first pixel structures. Each of the first pixel structures emits light with a first wavelength. Please refer to FIGS. 1 - 20 for a specific procedure of the first light emitting part.

Please refer to FIG. 1, a substrate 100 is provided.

In this example, the substrate 100 needs to be retained after the micro light emitting diode chip is finally formed. The substrate 100 is used as a base to carry various layers of component structures formed subsequently.

In this example, the substrate 100 is made of silicon (Si).

Please refer to FIG. 2, an insulating layer 101 is formed on the substrate 100; and a first metal material sublayer 102 is formed on the insulating layer 101.

In this example, the first metal material sublayer 102 is used to connect by bonding with an epitaxial part that subsequently forms first pixel structures.

In this example, the insulating layer 101 is made of a material including one or more selected from a group consisting of silicon dioxide (SiO₂), silicon nitride (SiNₓ), silicon oxynitride (SiON), titanium dioxide (TiO₂), and alumina (Al₂O₃).

In this example, the first metal material sublayer 102 is made of a non-transparent metal material, and in one embodiment, of chromium (Cr), titanium (Ti), platinum (Pt), gold (Au), tin (Sn), aluminum (Al), nickel (Ni), copper (Cu), or silver (Ag).

Please refer to FIG. 3, a first epitaxial substrate 103 is provided.

In this example, the first epitaxial substrate 103 is used as a base for an epitaxial part that forms the first light emitting part, and needs to be removed after the epitaxial part is grown.

In this example, either a silicon substrate or a sapphire substrate may be adopted as the first epitaxial substrate 103.

Please refer to FIG. 4, a stacked second epitaxial material layer 104, a first multiple quantum well material layer 105, a first epitaxial material layer 106, and a second metal material sublayer 107 are formed sequentially on the first epitaxial substrate 103.

In this example, the first multiple quantum well material layer 105 is formed between the first epitaxial material layer 106 and the second epitaxial material layer 104, and forms several first pixel structures after a subsequent pattern etching treatment.

In this example, the first epitaxial material layer 106 and the second epitaxial material layer 104 may be made of gallium nitride (GaN), indium gallium nitride (InGaN), aluminum gallium indium phosphide (AlGaInP) or other Group III-V semiconductor materials. The first multiple quantum well material layer 105 may be made of gallium nitride, indium gallium nitride, aluminum indium phosphide (AlGaP) or gallium indium phosphide (GaInP), and gallium nitride and indium gallium nitride materials are used to produce blue light or green light, and indium gallium nitride, aluminum indium phosphide and gallium indium phosphide materials are used to produce red light.

In this example, a first ohmic contact material layer 108 is further formed between the first epitaxial material layer 106 and the second metal material sublayer 107. The first ohmic contact material layer 108 is used to reduce contact resistance between the first epitaxial material layer 106 and the second metal material sublayer 107.

In this example, the first ohmic contact material layer 108 is made of a transparent conductive material. The transparent conductive material includes transparent metal materials or transparent conductive oxide materials. The transparent conductive oxide materials may be, but not limited to, N-type oxide semiconductors, in one embodiment indium tin oxide.

In this example, the second metal material sublayer 107 is made of a non-transparent metal material, and in one embodiment, of chromium, titanium, platinum, gold, tin, aluminum, nickel, copper, or silver.

Please refer to FIG. 5, the first metal material sublayer 102 and the second metal material sublayer 107 are bonded.

In this example, by bonding the first metal material sublayer 102 and the second metal material sublayer 107, the epitaxial part forming the first light emitting part is combined with the substrate 100 to form an overall structure.

In this example, a hybrid bonding method is adopted to bond the first metal material sublayer 102 and the second metal material sublayer 107.

In this example, bonded first metal material sublayer 102 and the second metal material sublayer 107 form a metal material layer 109.

In this example, since the metal material layer 109 is formed by the first metal material sublayer 102 and the second metal material sublayer 107 by bonding, material of the metal material layer 109 is the same as those of the first metal material sublayer and the second metal material sublayer.

Please refer to FIG. 6, the first epitaxial substrate 103 is removed.

In this example, since the first epitaxial substrate 103 is only a temporary substrate used to form the epitaxial part, it is necessary to remove the first epitaxial substrate 103 after bonding the first metal material sublayer 102 and the second metal material sublayer 107.

Please continue to refer to FIG. 6, in this example, after removing the first epitaxial substrate 103, the method further includes etching the second epitaxial material layer 104; and after etching a part of the second epitaxial material layer 104, forming a fourth ohmic contact material layer 110 on the second epitaxial material layer 104.

In this example, the fourth ohmic contact material layer 110 is made of a transparent conductive material. The transparent conductive material includes transparent metal materials or transparent conductive oxide materials. The transparent conductive oxide materials may be, but not limited to, N-type oxide semiconductors, in one embodiment indium tin oxide.

In this example, since a surface of the second epitaxial material layer 104 will be oxidized after the first epitaxial substrate 103 is removed, in order to remove an oxide layer, the part of the second epitaxial material layer 104 is etched.

In this example, the fourth ohmic contact material layer 110 formed on the second epitaxial material layer 104 is thin, and functions to test electrical contact performance between the fourth ohmic contact material layer 110 and the second epitaxial material layer 104.

Please refer to FIG. 7, the second epitaxial material layer 104, the first multiple quantum well material layer 105, and the first epitaxial material layer 106 are pattern etched, until the first ohmic contact material layer 108 is exposed, to form several discrete first pixel structures, and each of the first pixel structures emits light with a first wavelength.

In this example, forming the first pixel structures includes forming a first epitaxial layer 106a, a second epitaxial layer 104a, and a first multiple quantum well layer 105a disposed between the first epitaxial layer 106a and the second epitaxial layer 104a. The first epitaxial layer 106a contains a first doped ion. The second epitaxial layer 104a contains a second doped ion. Electrical types of the first doped ion and the second doped ion are different. Here, the first epitaxial layer 106a is formed by pattern etching on the first epitaxial material layer 106; the first multiple quantum well layer 105a is formed by pattern etching on the first multiple quantum well material layer 105; and the second epitaxial layer 104a is formed by pattern etching on the second epitaxial material layer 104.

In this example, since the first epitaxial layer 106a and the second epitaxial layer 104a are formed by pattern etching on the first epitaxial material layer 106 and the second epitaxial material layer 104, respectively, materials of the first epitaxial layer 106a and the second epitaxial layer 104a are the same as those of the first epitaxial material layer 106 and the second epitaxial material layer 104, respectively. The first multiple quantum well layer 105a is formed by pattern etching on the first multiple quantum well material layer 105, and material of the first multiple quantum well layer 105a is the same as that of the first multiple quantum well material layer 105.

In this example, the first doped ion in the first epitaxial layer 106a is a P-type doped ion, and the second doped ion in the second epitaxial layer 104a is an N-type doped ion.

It should be noted that, the reason why a multiple quantum well layer can emit light of different colors is mainly because they have specific physical properties that allow recombination of electrons and holes to occur between different energy levels, thus emitting light with different wavelengths.

The technical principles of multiple quantum well layers involve a fundamental concept of quantum physics, where the energy states of electrons and holes are confined to a specific region. This confinement leads to discrete energy levels. When electrons transition from high to low energy levels, photons are released. And, energy of the photons depends on energy difference between the energy levels. Since a structure of the multiple quantum well layer allows precise control over positions of these energy levels, wavelength of an emitted light, i.e., color of the emitted light, can be precisely controlled.

In one embodiment, a multiple quantum well layer consists of two or more different thin layers of semiconductor material superimposed alternately. Thicknesses and selected materials of these layers determine characteristics of an energy level. By adjusting the thicknesses and materials of these thin layers, recombination process of electrons and holes can be precisely controlled, thereby controlling the wavelength of the emitted light to emit light of different colors. For example, by adjusting structural parameters of the an InGaAs/InGaAsP multiple quantum well layer, laser outputs with wavelengths of 1.3 microns and 1.5 microns can be obtained. The light with these specific wavelengths corresponds to different colors required in communication and display technologies.

In addition, application of a multiple quantum well layer is not limited to emitting a single color of light. Output of multiple colors can be achieved by designing and adjusting a combination and structures of materials, which is of great significance for display technology, optical communication, and other fields. For example, quantum dot technology can achieve full-color display by controlling size and material of a quantum dot, which is widely used in modern display technology.

In this example, the light with the first wavelength corresponds to light of a first color. The light of the first color includes red light, green light or blue light.

Please continue to refer to FIG. 7, in a process of pattern etching in this example, the method further includes etching the fourth ohmic contact material layer 110, to form a fourth ohmic contact layer 110a on the second epitaxial layer 104a.

In this example, the fourth ohmic contact layer 110a is formed by pattern etching on the fourth ohmic contact material layer 110, and materials of the fourth ohmic contact layer 110a and the fourth ohmic contact material layer 110 are the same. Here, the fourth ohmic contact layer 110a is made of a transparent metal material to reduce blocking of light emitted from the first pixel structures.

Please refer to FIGS. 8-10. FIG. 8 is a schematic top view of a relative position of the metal layer 109a and the several first pixel structures, with omitting part of the structure. FIG. 9 is a schematic enlarged sectional view along the A-A line in FIG. 8. FIG. 10 is a schematic enlarged sectional view along the B-B line in FIG. 8. After forming the several first pixel structures, the metal material layer 109 and the first ohmic contact material layer 108 are etched to form a metal layer 109a and a first ohmic contact layer 108a.

In this example, forming the metal layer 109a includes forming several first metal strips 1091 arranged in parallel in a first direction X and extending in a second direction Y, the first direction X is perpendicular to the second direction Y; forming a first bus 1092 extending in the first direction X, and the several first metal strips 1091 are electrically connected with the first bus 1092, respectively; forming several second metal strips 1093 arranged in parallel in the first direction X and extending in the second direction Y, and the several first metal strips 1091 and the several second metal strips 1093 are arranged at intervals; and forming a second bus 1094 extending in the first direction X, and the several second metal strips 1093 are electrically connected with the second bus 1094, respectively.

In this example, the first ohmic contact layer 108a is formed on the first metal strips 1091, the second metal strips 1093, the first bus 1092 and the second bus 1094; and the several first pixel structures are electrically connected to the first ohmic contact layer 108a, respectively.

In this example, the first ohmic contact layer 108a is formed by pattern etching on the first ohmic contact material layer 108, and materials of the first ohmic contact layer 108a and the first ohmic contact material layer 108 are the same. Here, the first ohmic contact layer 108a is made of a transparent metal material to reduce blocking of light emitted from the first pixel structures.

In this example, the metal layer 109a is formed by pattern etching on the metal material layer 109, and materials of the metal layer 109a and the metal material layer 109 are the same. Here, the metal layer 109a is made of a non-transparent metal material, which can not only meet design requirements of the electrical connection between the first pixel structures, the non-transparent metal material can also play a role in light reflection, and can emit the light emitted from the first pixel structures and the second pixel structures towards a predetermined light emitting surface.

In this example, the several first pixel structures are electrically connected with the several first metal strips 1091, respectively. And, the several first pixel structures are arranged in an array along the first direction X and the second direction Y.

In this example, the first epitaxial layer 106a of the several first pixel structures is electrically connected with the several first metal strips 1091, respectively.

In this example, the first epitaxial layer 106a of the several first pixel structures is electrically connected with several first ohmic contact layers 108a. Contact resistance of direct electrical connection between the first epitaxial layer 106a and the metal layer 109a can be reduced by the first ohmic contact layer 108a.

Please refer to FIGS. 11 and 12, view directions of FIGS. 11 and 9 are the same, and view directions of FIGS. 12 and 10 are the same. After forming the metal layer 109a and the first ohmic contact layer 108a, the first dielectric sublayer 111a is formed.

In this example, the first dielectric sublayer 111a is disposed on and covers the several first pixel structures.

In this example, the first dielectric sublayer 111a may be made of a material including silicon dioxide, silicon nitride or alumina.

Please continue to refer to FIGS. 11 and 12, in this example, before forming the first dielectric sublayer 111a, the method further includes forming a first passivation layer 112 on an exposed surface of the first pixel structures, on an exposed surface of the metal layer 109a, on an exposed surface of the first ohmic contact layer 108a, and on an exposed surface of the fourth ohmic contact layer 110a.

In this example, the first passivation layer 112 may be made of a material including silicon dioxide, silicon nitride or alumina.

In this example, the first dielectric sublayer 111a further covers the first passivation layer 112.

Please refer to FIGS. 13 - 15. FIG. 13 is a schematic top view of a relative position of the metal layer 109a, the several first pixel structures and the second ohmic contact layer 113, with omitting part of the structure. FIG. 14 is a schematic enlarged sectional view along the C-C line in FIG. 13. FIG. 15 is a schematic enlarged sectional view along the D-D line in FIG. 13. Several second ohmic contact layers 113 are formed, arranged in parallel in the second direction Y and extending in the first direction X. Each of the second ohmic contact layers 113 is electrically connected with the several first pixel structures arranged in the first direction X.

It should be noted that, in this example, in order to ensure that the formed second ohmic contact layers 113 can be electrically connected with the first pixel structures, before forming the second ohmic contact layers 113, it is also necessary to etch the first dielectric sublayer 111a and the first passivation layer 112 covered on the first pixel structures to expose the fourth ohmic contact layer 110a on each of the first pixel structures, to ensure that the second ohmic contact layers 113 are electrically connected with corresponding first pixel structures.

In this example, the second ohmic contact layers 113 are electrically connected with the second epitaxial layer 104a of the first pixel structures.

In this example, the second ohmic contact layers 113 are disposed on the first dielectric sublayer 111a.

In this example, a method for forming the second ohmic contact layers 113 includes forming a second ohmic contact material layer (not shown); and pattern etching the second ohmic contact material layer to form several second ohmic contact layers 113.

In this example, the second ohmic contact layers 113 are made of a transparent conductive material including transparent metal materials or transparent conductive oxide materials. The transparent conductive oxide materials may be, but not limited to, N-type oxide semiconductors, in one embodiment indium tin oxide. Here, the second ohmic contact layers 113 are made of a transparent metal material to reduce blocking of light emitted from the first pixel structures.

Please refer to FIGS. 16 and 17. View directions of FIGS. 16 and 14 are the same. View directions of FIGS. 17 and 15 are the same. After forming the second ohmic contact layers 113, a second dielectric sublayer 111b is formed. The second dielectric sublayer 111b is disposed on the first dielectric sublayer 111a and covers the second ohmic contact layers 113.

In this example, the first dielectric sublayer 111a and the second dielectric sublayer 111b together constitute a first dielectric layer 111.

In this example, the second dielectric sublayer 111b is made of a material including silicon dioxide, silicon nitride or alumina.

Please refer to FIGS. 18 - 20. FIG. 18 is a schematic top view of a relative position of the metal layer 109a, the several first pixel structures, the second ohmic contact layers 113, first conductive plugs 114, second conductive plugs 115, third conductive plugs 116 and fourth conductive plugs 117, with omitting part of the structure. FIG. 19 is a schematic enlarged sectional view along the E-E line in FIG. 18. FIG. 20 is a schematic enlarged sectional view along the F-F line in FIG. 18. Several first conductive plugs 114 are formed, electrically connected with the several second ohmic contact layers 113, respectively. Several second conductive plugs 115 are formed, electrically connected with the several second metal strips 1093, respectively. Several third conductive plugs 116 are formed, electrically connected with the first bus 1092, respectively. Several fourth conductive plugs 117 are formed, electrically connected with the second bus 1094, respectively.

In this example, a surface of the second dielectric sublayer 111b exposes the first conductive plugs 114, the second conductive plugs 115, the third conductive plugs 116, and the fourth conductive plugs 117. The first conductive plugs 114 are formed only in the second dielectric sublayer 111b. At the same time, the second conductive plugs 115, the third conductive plugs 116 and the fourth conductive plugs 117 are formed only in the first dielectric sublayer 111a and in the second dielectric sublayer 111b.

In this example, the first conductive plugs 114, the second conductive plugs 115, the third conductive plugs 116 and the fourth conductive plugs 117 are made of copper.

At this point, the procedure of the first light emitting part is completed.

After forming the first light emitting part, the method further includes forming a second light emitting part. Forming the second light emitting part includes forming several second pixel structures corresponding to the first pixel structures. Each of the second pixel structures emits light with a second wavelength. The first wavelength is different from the second wavelength. For details on a formation procedure of the second light emitting part, please refer to FIGS. 21 - 31.

Please refer to FIG. 21, a second epitaxial substrate 200 is provided.

In this example, the second epitaxial substrate 200 is used as a base for an epitaxial part that forms the second light emitting part, and needs to be further removed after the epitaxial part is grown.

In this example, either a silicon substrate or a sapphire substrate may be adopted as the second epitaxial substrate 200.

Please refer to FIG. 22, a stacked fourth epitaxial material layer 201, a second multiple quantum well material layer 202, and a third epitaxial material layer 203 are formed sequentially on the second epitaxial substrate 200.

In this example, the second multiple quantum well material layer 202 is formed between the third epitaxial material layer 203 and the fourth epitaxial material layer 201, and forms several second pixel structures after a subsequent pattern etching treatment.

In this example, the third epitaxial material layer 203 and the fourth epitaxial material layer 201 may be made of gallium nitride, indium gallium nitride, aluminum gallium indium phosphide or other Group III-V semiconductor materials. The second multiple quantum well material layer 202 may be made of gallium nitride, indium gallium nitride, aluminum indium phosphide, or gallium indium phosphide.

In this example, a fifth ohmic contact material layer 204 is further formed on the third epitaxial material layer 203. The fifth ohmic contact material layer 204 formed on the third epitaxial material layer 203 is very thin, and functions to test electrical contact performance between the fifth ohmic contact material layer 204 and the third epitaxial material layer 203.

In this example, the fifth ohmic contact material layer 204 is made of a transparent conductive material. The transparent conductive material includes transparent metal materials or transparent conductive oxide materials. The transparent conductive oxide materials may be, but not limited to, N-type oxide semiconductors, in one embodiment indium tin oxide.

Please refer to FIG. 23, the third epitaxial material layer 203, the second multiple quantum well material layer 202, and the fourth epitaxial material layer 201 are pattern etched to form several second pixel structures.

In this example, forming the second pixel structures includes forming a third epitaxial layer 203a, a fourth epitaxial layer 201a, and a second multiple quantum well layer 202a disposed between the third epitaxial layer 203a and the fourth epitaxial layer 201a. The third epitaxial layer 203a contains the first doped ion. The fourth epitaxial layer 201a contains the second doped ion. Here, the third epitaxial layer 203a is formed by pattern etching on the third epitaxial material layer 203, the second multiple quantum well layer 202a is formed by pattern etching on the second multiple quantum well material layer 202, and the fourth epitaxial layer 201a is formed by pattern etching on the fourth epitaxial material layer 201.

In this example, since the third epitaxial layer 203a and the fourth epitaxial layer 201a are formed by pattern etching on the third epitaxial material layer 203 and the fourth epitaxial material layer 201, respectively, materials of the third epitaxial layer 203a and the fourth epitaxial layer 201a are the same as those of the third epitaxial material layer 203 and the fourth epitaxial material layer 201, respectively. The second multiple quantum well layer 202a is formed by pattern etching on the second multiple quantum well material layer 202, and materials of the second multiple quantum well layer 202a and the second multiple quantum well material layer 202 are the same.

In this example, in a process of pattern etching, instead of completely etching through the fourth epitaxial material layer 201, a part of the fourth epitaxial material layer 201 is retained and the fourth epitaxial layers 201a of the several second pixel structures are connected to each other.

In this example, in the process of pattern etching, the fifth ohmic contact material layer 204 is further etched to form a fifth ohmic contact layer 204a electrically connected with the third epitaxial layer 203a of each of the second pixel structures.

In this example, the fifth ohmic contact layer 204a is formed by pattern etching on the fifth ohmic contact material layer 204, and materials of the fifth ohmic contact layer 204a and the fifth ohmic contact material layer 204 are the same. Here, the fifth ohmic contact layer 204a is made of a transparent metal material to reduce blocking of light emitted from the second pixel structures.

In this example, light emitting principle of the second pixel structures is the same as that of the first pixel structures, which will not be repeated here. Please refer to the illustration of the light emitting principle of the multiple quantum well layer in FIG. 7.

In this example, the light with the second wavelength corresponds to light of a second color. The light of the second color includes red light, green light or blue light. The first wavelength is different from the second wavelength, and corresponding light of the first color and light of the second color are different.

Please refer to FIG. 24, after forming the several second pixel structures, a second passivation layer 205 is formed on an exposed surface of the second pixel structures.

In this example, the second passivation layer 205 may be made of a material including silicon dioxide, silicon nitride or alumina.

In this example, in one embodiment, the second passivation layer 205 includes three parts (not shown). A first part covers a surface of the several second pixel structures, is disposed on the fifth ohmic contact layer 204a, and exposes a part of the fifth ohmic contact layer 204a. A second part covers a side of the several second pixel structures. A third part covers a surface of the fourth epitaxial material layer 201 in a gap between adjacent second pixel structures. The first part, the second part and the third part of the second passivation layer 205 are connected to each other.

In some variations, the second passivation layer 205 may include only the second part and the third part described above. And, a top of the second part of the second passivation layer 205 is flush with a top of the fifth ohmic contact layer 204a. In one embodiment, a height of the top of the second part is slightly lower than a height of a top surface of the third epitaxial layer 203a.

Please refer to FIGS. 25 - 27. FIG. 25 is a schematic top view of a relative position of the third ohmic contact layer 206 and corresponding second pixel structures, with omitting part of the structure. FIG. 26 is a schematic enlarged sectional view along the G-G line in FIG. 25. FIG. 27 is a schematic enlarged sectional view along the H-H line in FIG. 25. After forming the second passivation layer 205, several third ohmic contact layers 206 are formed. Each of the third ohmic contact layers 206 is electrically connected with a corresponding second pixel structure.

It should be noted that, in this example, in order to ensure that the formed third ohmic contact layers 206 can be electrically connected with the second pixel structures, before forming the third ohmic contact layers 206, it is also necessary to etch the second passivation layer 205 covered on the second pixel structures to expose the fifth ohmic contact layer 204a on each of the second pixel structures, to ensure that the third ohmic contact layers 206 are electrically connected with corresponding second pixel structures.

In this example, the third ohmic contact layers 206 are electrically connected with the third epitaxial layer 203a of the second pixel structures.

In this example, a method for forming the third ohmic contact layers 206 includes forming a third ohmic contact material layer (not shown); and pattern etching the third ohmic contact material layer to form several third ohmic contact layers 206.

In this example, the third ohmic contact layers 206 are made of a transparent conductive material including transparent metal materials or transparent conductive oxide materials. The transparent conductive oxide materials may be, but not limited to, N-type oxide semiconductors, in one embodiment indium tin oxide. Here, the third ohmic contact layers 206 are made of a transparent metal material to reduce blocking of light emitted from the second pixel structures.

Please refer to FIGS. 28 and 29. View directions of FIGS. 28 and 26 are the same. View directions of FIGS. 29 and 27 are the same. After forming the third ohmic contact layers 206, a second dielectric layer 207 is formed.

In this example, the second dielectric layer 207 covers the several second pixel structures and the several third ohmic contact layers 206.

In this example, the second dielectric layer 207 is made of a material including silicon dioxide, silicon nitride or alumina.

Please refer to FIGS. 30 and 31. FIG. 30 is a schematic top view of a relative position of the third ohmic contact layers 206, the second pixel structures, the fourth epitaxial material layer 201, fifth conductive plugs 208, sixth conductive plugs 209, seventh conductive plugs 210 and eighth conductive plugs 211, with omitting part of the structure. FIG. 31 is a schematic enlarged sectional view along the I-I line in FIG. 30. After forming the second dielectric layer 207, several fifth conductive plugs 208 are formed, electrically connected with the fourth epitaxial layer 201a of the second pixel structures, respectively; several sixth conductive plugs 209 are formed, electrically connected with corresponding third ohmic contact layers 206, respectively; several seventh conductive plugs 210 are formed; and several eighth conductive plugs 211 are formed.

It should be noted that, in this example, the formed several fifth conductive plugs 208 need to run through retained fourth epitaxial material layer 201, to ensure that after sequentially removing the second epitaxial layer 104a, the fifth conductive plugs 208 can be exposed to be electrically connected with an electrode plate formed later. At this time, the formed seventh conductive plugs 210 and the eighth conductive plugs 211 are still electrically connected with the retained fourth epitaxial material layer 201, but in a subsequent procedure, it is necessary to remove the fourth epitaxial material layer 201 electrically connected with the seventh conductive plugs 210 and the eighth conductive plugs 211, in order to ensure that the chip can be controlled to emitting monochromatic light.

In this example, the second dielectric layer 207 exposes a surface of the fifth conductive plugs 208, a surface of the sixth conductive plugs 209, a surface of the seventh conductive plugs 210, and a surface of the eighth conductive plugs 211, to ensure electrically connection with corresponding first conductive plugs 114, the second conductive plugs 115, the third conductive plugs 116, and the fourth conductive plugs 117 upon subsequent bonding.

In this example, the fifth conductive plugs 208, the sixth conductive plugs 209, the seventh conductive plugs 210 and the eighth conductive plugs 211 are made of copper.

At this point, the procedure of the second light emitting part is completed.

Please refer to FIGS. 32 and 33. View directions of FIGS. 32 and 19 are the same. View directions of FIGS. 33 and 20 are the same. The first light emitting part and the second light emitting part are bonded, and the first pixel structures and the second pixel structures corresponding thereto are provided relative to each other along a stacking direction of components. And, the first dielectric layer 111 and the second dielectric layer 207 are connected.

With light emitting pixel structures emitting light with different wavelengths being integrated into a same chip, stacking of pixel structures of different colors can be completed at a same chip end, which can effectively reduce a volume of chips of different colors which are used in combination.

In this example, after bonding the first light emitting part and the second light emitting part, the second dielectric sublayer 111b is connected with the second dielectric layer 207; the several fifth conductive plugs 208 are connected with corresponding several first conductive plugs 114 by bonding, respectively; the several sixth conductive plugs 209 are connected with corresponding several second conductive plugs 115 by bonding, respectively; the several seventh conductive plugs 210 are electrically connected with corresponding several third conductive plugs 116, respectively; and the several eighth conductive plugs 211 are electrically connected with corresponding several fourth conductive plugs 117, respectively.

In this example, the first light emitting part and the second light emitting part are bonded by a hybrid bonding method.

Please continue to refer to FIGS. 32 and 33, in this example, after bonding the first light emitting part and the second light emitting part, the second epitaxial substrate 200 is removed.

In this example, after the second epitaxial substrate 200 is removed, the retained fourth epitaxial material layer 201 is further partially etched to remove an oxidized part on a surface of the fourth epitaxial material layer 201.

Please continue to refer to FIGS. 32 and 33, after the second epitaxial substrate 200 is removed, a sixth ohmic contact material layer 212 is formed on the exposed fourth epitaxial material layer 201.

In this example, the sixth ohmic contact material layer 212 is made of a transparent conductive material including transparent metal materials or transparent conductive oxide materials. The transparent conductive oxide materials may be, but not limited to, N-type oxide semiconductors, in one embodiment indium tin oxide. The function of the sixth ohmic contact material layer 212 is to reduce contact resistance between the rest of the device structure and the fourth epitaxial material layer 201.

Please continue to refer to FIG. 33, in this example, along the stacking direction of components, the first pixel structures have a first projection region, the second pixel structures corresponding to the first pixel structures have a second projection region, and the first projection region and the second projection region are completely overlapping. Complete overlap between the first projection region and the second projection region allows for best mixing effect of the light of the first color and the light of the second color.

In other examples, along the stacking direction of components, the first pixel structures have a first projection region, the second pixel structures corresponding to the first pixel structures have a second projection region, and the first projection region and the second projection region may be at least partially overlapping.

Please refer to FIG. 34. FIG. 34 is a schematic top view of a relative position of the fifth conductive plugs 208, the seventh conductive plugs 210, the eighth conductive plugs 211, a first electrode plate 213, a second electrode plate 214 and a third electrode plate 215. After bonding the first light emitting part and the second light emitting part, the first electrode plate 213 is formed, electrically connected with the several fifth conductive plugs 208; a second electrode plate 214 is formed, electrically connected with the several seventh conductive plugs 210; a third electrode plate 215 is formed, electrically connected with the several eighth conductive plugs 211.

Please continue to refer to FIG. 34, it should be noted that, in this example, the seventh conductive plugs 210 and the eighth conductive plugs 211 are not exposed after bonding, and the seventh conductive plugs 210 and the eighth conductive plugs 211 are further electrically connected with the fourth epitaxial material layer 201. Therefore, in order to induce the seventh conductive plugs 210 and the eighth conductive plugs 211 separately to ensure that the chip can be controlled to emit monochromatic light, before forming the first electrode plate 213, the second electrode plate 214 and the third electrode plate 215, the sixth ohmic contact material layer 212 and the fourth epitaxial material layer 201 electrically connected with the seventh conductive plugs 210 and the eighth conductive plugs 211 need to be removed. At the same time, after removing the corresponding sixth ohmic contact material layer 212, the sixth ohmic contact material layer 212 is made to form a sixth ohmic contact layer.

With the three electrode plates, and the first electrode plate is used as a common electrode of same doped epitaxial layers in the first pixel structures and the second pixel structures, different power supply combinations of the three electrode plates can realize monochrome light emission of the first pixel structures, monochromatic light emission of the second pixel structures, and mixed light emission of the first pixel structures and the second pixel structures, to meet requirements of a variety of use scenarios.

In this example, a method for forming the first electrode plate 213, the second electrode plate 214 and the third electrode plate 215 includes forming an electrode plate material layer; pattern etching the electrode plate material layer to form the first electrode plate 213, the second electrode plate 214 and the third electrode plate 215.

In this example, the first electrode plate 213, the second electrode plate 214 and the third electrode plate 215 may be made of chromium, titanium, platinum, gold, tin, aluminum, nickel, copper or silver.

The embodiments of the present disclosure provide a micro light emitting diode chip. Please continue to refer to FIGS. 1 -34, the micro light emitting diode chip includes a first light emitting part including several discrete first pixel structures, each of the first pixel structures emits light with a first wavelength; and a second light emitting part including several second pixel structures corresponding to the first pixel structures, each of the second pixel structures emits light with a second wavelength, and the first wavelength is different from the second wavelength; the first light emitting part and the second light emitting part are connected by bonding, and the first pixel structures and the second pixel structures corresponding thereto are provided relative to each other along a stacking direction of components.

With light emitting pixel structures emitting light with different wavelengths being integrated into a same chip, stacking of pixel structures of different colors can be completed at a same chip end, which can effectively reduce a volume of chips of different colors which are used in combination.

In this example, the first light emitting part further includes a first dielectric layer 111 disposed on and covering the first pixel structures; the second light emitting part further includes a second dielectric layer 207 disposed on and covering the second pixel structures; the first dielectric layer 111 and the second dielectric layer 207 are connected by bonding, to connect the first light emitting part and the second light emitting part by bonding.

In this example, along the stacking direction of components, the first pixel structures have a first projection region, the second pixel structures corresponding to the first pixel structures have a second projection region, and the first projection region and the second projection region are completely overlapping. Complete overlapping between the first projection region and the second projection region allows for best mixing effect of the light of the first color and the light of the second color.

In other examples, along the stacking direction of components, the first pixel structures have a first projection region, the second pixel structures corresponding to the first pixel structures have a second projection region, and the first projection region and the second projection region may be at least partially overlapping.

In this example, the first pixel structure includes a first epitaxial layer 106a, a second epitaxial layer 104a, and a first multiple quantum well layer 105a disposed between the first epitaxial layer 106a and the second epitaxial layer 104a. The first epitaxial layer 106a contains a first doped ion. The second epitaxial layer 104a contains a second doped ion. Electrical types of the first doped ion and the second doped ion are different.

In this example, the first light emitting part further includes a metal layer 109a. The metal layer 109a includes several first metal strips 1091 arranged in parallel in a first direction X and extending in a second direction Y, the first direction X is perpendicular to the second direction Y; the first bus 1092 extending in the first direction X, and the several first metal strips 1091 are electrically connected to the first bus 1092, respectively; several second metal strips 1093 arranged in parallel in the first direction X and extending in the second direction Y, the several first metal strips 1091 and the several second metal strips 1093 are arranged at intervals; and a second bus 1094 extending in the first direction X, and the several second metal strips 1093 are electrically connected to the second bus 1094 respectively.

In this example, the metal layer 109a is made of a non-transparent metal material. The non-transparent metal material includes chromium, titanium, platinum, gold, tin, aluminum, nickel, copper, or silver. The metal layer 109a is made of a non-transparent metal material, which can not only meet design requirements of the electrical connection between the first pixel structures, the non-transparent metal material can also play a role in light reflection, and can emit light emitted from the first pixel structures and the second pixel structures towards a predetermined light emitting surface.

In this example, the several first pixel structures are electrically connected with the several first metal strips 1091, respectively. And, the several first pixel structures are arranged in an array along the first direction X and the second direction Y.

In this example, the first epitaxial layer 106a of the several first pixel structures is electrically connected with the several first metal strips 1091, respectively.

In this example, the first light emitting part further includes a first ohmic contact layer 108a disposed on the first metal strips 1091, on the second metal strips 1093, on the first bus 1092 and on the second bus 1094. The several first pixel structures are electrically connected with the first ohmic contact layer 108a, respectively.

In this example, the first epitaxial layer 106a of the several first pixel structures is electrically connected with several first ohmic contact layers 108a.

In this example, the first ohmic contact layers 108a are made of a transparent conductive material including transparent metal materials or transparent conductive oxide materials. The transparent conductive oxide materials may be, but not limited to, N-type oxide semiconductors, in one embodiment indium tin oxide.

In this example, the first light emitting part further includes several second ohmic contact layers 113 arranged in parallel in the second direction Y and extending in the first direction X. Each of the second ohmic contact layers 113 is electrically connected with the several first pixel structures arranged in the first direction X, respectively.

In this example, the first dielectric layer 111 includes a first dielectric sublayer 111a disposed on and covering the several first pixel structures. The second ohmic contact layers 113 are disposed on the first dielectric sublayer 111a.

In this example, the first dielectric layer 111 further includes a second dielectric sublayer 111b disposed on the first dielectric sublayer 111a and covering the second ohmic contact layers 113.

In this example, the second ohmic contact layers 113 are made of a transparent conductive material including transparent metal materials or transparent conductive oxide materials. The transparent conductive oxide materials may be, but not limited to, N-type oxide semiconductors, in one embodiment indium tin oxide.

In this example, the second dielectric sublayer 111b is connected with the second dielectric layer 207 by bonding.

In this example, the first light emitting part further includes several first conductive plugs 114 electrically connected with the several second ohmic contact layers 113, respectively; several second conductive plugs 115 electrically connected with the several second metal strips 1093, respectively; several third conductive plugs 116 electrically connected with the first bus 1092, respectively; and several fourth conductive plugs 117 electrically connected with the second bus 1094, respectively.

In this example, the second pixel structures include a third epitaxial layer 203a, a fourth epitaxial layer 201a, and a second multiple quantum well layer 202a disposed between the third epitaxial layer 203a and the fourth epitaxial layer 201a. The third epitaxial layer 203a contains the first doped ion. The fourth epitaxial layer 201a contains the second doped ion.

In this example, the fourth epitaxial layers 201a of the several second pixel structures are connected to each other.

In this example, the second light emitting part further includes several third ohmic contact layers 206. Each of the third ohmic contact layers 206 is electrically connected with a corresponding second pixel structure.

In this example, each of the third ohmic contact layers 206 is electrically connected with the third epitaxial layer 203a of a corresponding second pixel structure.

In this example, the third ohmic contact layers 206 are made of a transparent conductive material including transparent metal materials or transparent conductive oxide materials. The transparent conductive oxide materials may be, but not limited to, N-type oxide semiconductors, in one embodiment indium tin oxide.

In this example, the second dielectric layer 207 further covers the several third ohmic contact layers 206.

In this example, the second light emitting part further includes several fifth conductive plugs 208 electrically connected with the fourth epitaxial layer 201a of the second pixel structures, respectively and connected with corresponding several first conductive plugs 114 by bonding, respectively; several sixth conductive plugs 209 electrically connected with corresponding third ohmic contact layers 206, respectively and connected with corresponding several second conductive plugs 115 by bonding, respectively; several seventh conductive plugs 210 electrically connected with corresponding third conductive plugs 116, respectively; and several eighth conductive plugs 211 electrically connected with corresponding several fourth conductive plugs 117, respectively.

In this example, the micro light emitting diode chip further includes a first electrode plate 213 electrically connected with the several fifth conductive plugs 208; a second electrode plate 214 electrically connected with the several seventh conductive plugs 210; and a third electrode plate 215 electrically connected with the several eighth conductive plugs 211.

With the three electrode plates, and the first electrode plate 213 is used as a common electrode of same doped epitaxial layers in the first pixel structures and the second pixel structures, different power supply combinations of the three electrode plates can realize monochrome light emission of the first pixel structures, monochromatic light emission of the second pixel structures, and mixed light emission of the first pixel structures and the second pixel structures, to meet requirements of a variety of use scenarios.

Although the present disclosure is disclosed as above, the present disclosure is not limited hereto. Various changes and modifications may be made in the art without departing from the spirit and scope of the present disclosure. Therefore, the scope of protection of the present disclosure shall be subject to the scope limited by the claims.

What is claimed is:

1. A micro light emitting diode chip, comprising:
a first light emitting part comprising several discrete first pixel structures, each of the first pixel structures emits light with a first wavelength; and
a second light emitting part comprising several second pixel structures corresponding to the first pixel structures, each of the second pixel structures emits light with a second wavelength, and the first wavelength is different from the second wavelength,
the first light emitting part and the second light emitting part are connected by bonding, and the first pixel structures and the second pixel structures corresponding thereto are provided relative to each other along a stacking direction of components.

2. The micro light emitting diode chip according to claim 1, wherein the first light emitting part further comprises a first dielectric layer disposed on and covering the first pixel structures; the second light emitting part further comprises a second dielectric layer disposed on and covering the second pixel structures; the first dielectric layer and the second dielectric layer are connected by bonding, to connect the first light emitting part and the second light emitting part by bonding.

3. The micro light emitting diode chip according to claim 1, wherein along the stacking direction of components, the first pixel structures have a first projection region, the second pixel structures corresponding to the first pixel structures have a second projection region, and the first projection region and the second projection region are completely or at least partially overlapping.

4. The micro light emitting diode chip according to claim 2, wherein the first pixel structures comprise a first epitaxial layer, a second epitaxial layer, and a first multiple quantum well layer disposed between the first epitaxial layer and the second epitaxial layer; the first epitaxial layer contains a first doped ion, the second epitaxial layer contains a second doped ion, and electrical types of the first doped ion and the second doped ion are different,
the first light emitting part further comprises a metal layer; the metal layer comprises:
several first metal strips arranged in parallel in a first direction and extending in a second direction, the first direction is perpendicular to the second direction;
a first bus extending in the first direction, and the several first metal strips are electrically connected to the first bus, respectively;
several second metal strips arranged in parallel in the first direction and extending in the second direction, the several first metal strips and the several second metal strips are arranged at intervals; and
a second bus extending in the first direction, and the several second metal strips are electrically connected to the second bus, respectively, and
the metal layer is made of a non-transparent metal material; and the non-transparent metal material comprises chromium, titanium, platinum, gold, tin, aluminum, nickel, copper, or silver.

5. The micro light emitting diode chip according to claim 4, wherein the first pixel structures are electrically connected with the several first metal strips, respectively, and the first pixel structures are arranged in an array along the first direction and the second direction;
the first epitaxial layer of the first pixel structures is electrically connected with the several first metal strips, respectively;
the first light emitting part further comprises a first ohmic contact layer disposed on the first metal strips, on the second metal strips, on the first bus and on the second bus; and
the first epitaxial layer of the first pixel structures is electrically connected with several of the first ohmic contact layers, respectively.

6. The micro light emitting diode chip according to claim 4, wherein the first light emitting part further comprises several second ohmic contact layers arranged in parallel in the second direction and extending in the first direction, and each of the second ohmic contact layers is electrically connected with the first pixel structures arranged in the first direction, respectively,
the first dielectric layer comprises:
a first dielectric sublayer disposed on and covering the first pixel structures; and
a second dielectric sublayer disposed on the first dielectric sublayer and covering the second ohmic contact layers,
the second ohmic contact layers are disposed on the first dielectric sublayer, and the second dielectric sublayer is connected with the second dielectric layer by bonding.

7. The micro light emitting diode chip according to claim 6, wherein the first light emitting part further comprises several first conductive plugs electrically connected with the several second ohmic contact layers, respectively; several second conductive plugs electrically connected with the several second metal strips, respectively; several third conductive plugs electrically connected with the first bus, respectively; and several fourth conductive plugs electrically connected with the second bus, respectively,
the second pixel structures comprise a third epitaxial layer, a fourth epitaxial layer, and a second multiple quantum well layer disposed between the third epitaxial layer and the fourth epitaxial layer; the third epitaxial layer contains the first doped ion, and the fourth epitaxial layer contains the second doped ion,
the fourth epitaxial layers of the several second pixel structures are connected to each other,
the second light emitting part further comprises several third ohmic contact layers, each of the third ohmic contact layers is electrically connected to a corresponding second pixel structure.

8. The micro light emitting diode chip according to claim 7, wherein each of the third ohmic contact layers is electrically connected with the third epitaxial layer of the corresponding second pixel structure,
the second light emitting part further comprises:
several fifth conductive plugs electrically connected with the fourth epitaxial layer of the second pixel structure, respectively and connected with corresponding several first conductive plugs by bonding, respectively;
several sixth conductive plugs electrically connected with a corresponding third ohmic contact layer, respectively and connected with corresponding several second conductive plugs by bonding, respectively;
several seventh conductive plugs electrically connected with corresponding several third conductive plugs, respectively; and
several eighth conductive plugs electrically connected with corresponding several fourth conductive plugs, respectively, and
the micro light emitting diode chip further comprises:
a first electrode plate electrically connected with the several fifth conductive plugs;
a second electrode plate electrically connected with the several seventh conductive plugs; and
a third electrode plate electrically connected with the several eighth conductive plug.

9. The micro light emitting diode chip according to claim 7, wherein the second dielectric layer further covers the several third ohmic contact layers.

10. A method for forming a micro light emitting diode chip, comprising:
forming a first light emitting part, and forming the first light emitting part comprises forming several discrete first pixel structures, each of the first pixel structures emits light with a first wavelength;
forming a second light emitting part, forming the second light emitting part comprises forming several second pixel structures corresponding to the first pixel structures, each of the second pixel structures emits light with a second wavelength, and the first wavelength is different from the second wavelength; and
bonding the first light emitting part and the second light emitting part, and the first pixel structures and the second pixel structures corresponding thereto are provided relative to each other along a stacking direction of components.

11. The method for forming a micro light emitting diode chip according to claim 10, wherein forming the first light emitting part further comprises forming a first dielectric layer on the first pixel structures, and the first dielectric layer covers the first pixel structures;
forming the second light emitting part further comprises forming a second dielectric layer on the second pixel structures, and the second dielectric layer covers the second pixel structures; and
bonding the first dielectric layer and the second dielectric layer, to connect the first light emitting part and the second light emitting part by bonding,
forming the first pixel structures comprises forming a first epitaxial layer, a second epitaxial layer, and a first multiple quantum well layer disposed between the first epitaxial layer and the second epitaxial layer; the first epitaxial layer contains a first doped ion, the second epitaxial layer contains a second doped ion, and electrical types of the first doped ion and the second doped ion are different,
forming the first light emitting part further comprises forming a metal layer; forming the metal layer comprises:
forming several first metal strips arranged in parallel in a first direction and extending in a second direction, the first direction is perpendicular to the second direction;
forming a first bus extending in the first direction, and the several first metal strips are electrically connected with the first bus, respectively;
forming several second metal strips arranged in parallel in the first direction and extending in the second direction, and the several first metal strips and the several second metal strips are arranged at intervals; and
forming a second bus extending in the first direction, and the several second metal strips are electrically connected with the second bus, respectively, and
the metal layer is made of a non-transparent metal material.

12. The method for forming a micro light emitting diode chip according to claim 10, wherein along the stacking direction of components, the first pixel structures have a first projection region, the second pixel structures corresponding to the first pixel structures have a second projection region, and the first projection region and the second projection region are completely or at least partially overlapping.

13. The method for forming a micro light emitting diode chip according to claim 11, wherein the first pixel structures are electrically connected with the several first metal strips, respectively, and the first pixel structures are arranged in an array along the first direction and the second direction,
the first epitaxial layer of the first pixel structures is electrically connected with the several first metal strips, respectively, and
forming the first light emitting part further comprises forming a first ohmic contact layer on the first metal strips, on the second metal strips, on the first bus and on the second bus; the first pixel structures are electrically connected with the first ohmic contact layer, respectively.

14. The method for forming a micro light emitting diode chip according to claim 13, wherein a method for forming the metal layer and the first ohmic contact layer comprises:
forming a metal material layer;
forming a first ohmic contact material layer on the metal material layer; and
etching the metal material layer and the first ohmic contact material layer, to form the metal layer and the first ohmic contact layer.

15. The method for forming a micro light emitting diode chip according to claim 13, wherein the first epitaxial layer of the first pixel structures is electrically connected with several of the first ohmic contact layers, respectively.

16. The method for forming a micro light emitting diode chip according to claim 11, wherein forming the first light emitting part further comprises forming several second ohmic contact layers arranged in parallel in the second direction and extending in the first direction, and each of the second ohmic contact layers is electrically connected with the first pixel structures arranged in the first direction.

17. The method for forming a micro light emitting diode chip according to claim 16, wherein forming the first dielectric layer comprises:
forming a first dielectric sublayer disposed on and covering the first pixel structures, and the second ohmic contact layers are disposed on the first dielectric sublayer; and
forming a second dielectric sublayer disposed on the first dielectric sublayer and covering the second ohmic contact layers,
upon bonding the first light emitting part and the second light emitting part, the second dielectric sublayer is connected with the second dielectric layer.

18. The method for forming a micro light emitting diode chip according to claim 16, wherein forming the first light emitting part further comprises:
forming several first conductive plugs electrically connected with the several second ohmic contact layers, respectively;
forming several second conductive plugs electrically connected with the several second metal strips, respectively;
forming several third conductive plugs electrically connected with the first bus, respectively; and
forming several fourth conductive plugs electrically connected with the second bus, respectively,
forming the second pixel structures comprises forming a third epitaxial layer, a fourth epitaxial layer, and a second multiple quantum well layer disposed between the third epitaxial layer and the fourth epitaxial layer; the third epitaxial layer contains the first doped ion, and the fourth epitaxial layer contains the second doped ion,
the fourth epitaxial layers of the several second pixel structures are connected to each other,
forming the second light emitting part further comprises forming several third ohmic contact layers, and each of the third ohmic contact layers is electrically connected to a corresponding second pixel structure.

19. The method for forming a micro light emitting diode chip according to claim 18, wherein each of the third ohmic contact layers is electrically connected with the third epitaxial layer of the corresponding second pixel structure,
forming the second light emitting part further comprises:
forming several fifth conductive plugs electrically connected with the fourth epitaxial layer of the second pixel structure, respectively;
forming several sixth conductive plugs electrically connected with a corresponding third ohmic contact layer, respectively;
forming several seventh conductive plugs; and
forming several eighth conductive plugs,
upon bonding the first light emitting part and the second light emitting part, the several fifth conductive plugs are connected with corresponding several first conductive plugs by bonding, respectively;
the several sixth conductive plugs are connected with corresponding several second conductive plugs by bonding, respectively;
the several seventh conductive plugs are electrically connected with corresponding several third conductive plugs, respectively; and
the several eighth conductive plugs are electrically connected with corresponding several fourth conductive plugs, respectively, and
after bonding the first light emitting part and the second light emitting part, the method further comprises:
forming a first electrode plate electrically connected with the several fifth conductive plugs;
forming a second electrode plate electrically connected with the several seventh conductive plugs; and
forming a third electrode plate electrically connected with the several eighth conductive plugs.

20. The method for forming a micro light emitting diode chip according to claim 18, wherein the second dielectric layer further covers the several third ohmic contact layers.
